(19) United States
(12) Patent Application Publication
(10) Pub. No.: US 2026/0221079 A1
(43) Pub. Date: Jul. 30, 2026

(54) WIDE COLOR GAMUT-TUNABLE LED ELEMENTS AND DISPLAY SYSTEMS AND METHODS THEREOF HAVING LESS UNDESIRABLE COLOR ARTIFACTS

(71) Applicant: INNOVATION SEMICONDUCTOR, INC., Rochester, NY (US)

(72) Inventors: Matthew T. HARTENSVELD, Wyckoff, NJ (US); Candice Helen BROWN ELLIOTT, Santa Rosa, CA (US)

(21) Appl. No.: 19/147,672

(22) PCT Filed: Jan. 11, 2024
(86) PCT No.: PCT/US2024/011249

§ 371 Date: Jul. 11, 2025

Related U.S. Application Data
(60) Provisional application No. 63/438,435, filed on Jan. 11, 2023.

(51) Int. Cl. G09G 3/32; H10H 20/812; H10H 20/816

(52) U.S. Cl. CPC G09G 3/32; H10H 20/812; H10H 20/8162; G09G 2310/08

(57) ABSTRACT

A color-tunable LED system that is configured to emit a variety of peak wavelengths of light in response to variations in a driving current density includes an n-type region, a p-type region, and a multiple quantum well (MQW) region formed between the n-type region and the p-type region. The MQW region includes parallel layers, each alloyed with a percentage of Indium to enable a range of light emission between 400 and 600 nm, and one or more shaped depressions formed within a portion of the parallel layers. Each of the one or more shaped depressions has a lower concentration of the alloyed percentage of the Indium than other portions of the parallel layers. Transition regions between the one or more shaped depressions and the other portions of the parallel layers have a higher concentration of the alloyed percentage of the Indium which decreases with distance from the one or more shaped depressions. Use of the monolithic color-tunable LED system can make use of a single LED to act as a pixel.

### CROSS-REFERENCE TO RELATED APPLICATION

This application is a continuation of International Application No. PCT/US2024/011249, filed Jan. 11, 2024, which claims the benefit of U.S. Provisional Application Ser. No. 63/438,435, filed Jan. 11, 2023, which are hereby incorporated by reference in their entirety.

### FIELD

This technology relates to color-tunable light emitting diodes, LED systems and LED display systems including such light emitting diodes and methods thereof.

### BACKGROUND

Displays based on inorganic light emitting diodes (LEDs), particularly smaller mini-LEDs and u-LEDs, are viewed by the display industry as an emerging successor to those including organic light emitting diodes (OLEDs) for many applications including both near eye displays and larger form factor displays viewed at a distance. They offer many advantages, including high efficiency, environmental ruggedness, greater scaling, and higher brightness.

However, the development of improved inorganic LEDs and LED displays has been hampered by issues relating to integration of separately fabricated red, green, and blue LEDs into a functional and controllable LED system capable of emitting light across the visible spectrum. Each LED includes layers of an electron rich n-type region, a hole rich p-type region, and a multiple quantum well (MQW) region between the n-type and p-type regions. The MQW region is composed of multiple individual quantum wells, which possess a smaller energy bandgap due to alloying, which are positioned between higher energy bandgap materials. The smaller energy bandgap quantum wells confine electrons and holes to facilitate recombination and corresponding light emission.

By way of example, blue and green LEDs are commonly based on the III-N material system. Indium is alloyed with GaN in different amounts to shrink the bandgap of the quantum wells. Where blue light can be produced with quantum wells containing ~10% Indium, additional Indium incorporation leads to longer wavelength emissions such as green. Use of only the III-N material system for blue, green, and red is limited due to the difficulties in incorporating the high levels of Indium utilized for red. As the Indium concentration increases, issues of strain and solubility arise. Conventionally, red emitters instead make use of the III-V material system with AlInGaP. Relying on these disunified material systems, associated respectively with blue and green and separately red, typically necessitates the separate manufacturing of each, followed by integration with Silicon-based control electronics in a display. This integration typically leads to higher costs and more complex manufacturing methods.

To avoid the need for separate LED growths, there have been three main approaches to develop higher efficiency red emitting and overall visible light emitting color tunable InGaN LEDs that reduce the integration issues noted above, namely Europium doping, use of a porous GaN substrate, or nanowire growth. Each of these approaches, however, suffers from issues of complex manufacturing of a display and compromised emission uniformity.

In addition, a key challenge confronting such displays is that conventionally such light emitting diodes only provided emission of a single fixed color. Thus, it was typical in prior art to transfer a set of light emitting diodes of various colors, usually substantially red, green, and blue. This then employed more than one emitter to provide a full color reproduction with concomitant increased manufacturing and electronic drive complexity and cost. This may be overcome using novel color tunable light emitting diodes to provide full color reproduction and image reconstruction with only one light emitting diode per pixel when constructed and operated in the manner herein disclosed.

### SUMMARY

Examples of this technology relate to color-tunable LEDs, LED systems and display systems, which can be monolithic in nature by using a common, single crystalline material system, configured to emit a variety of peak wavelengths of light in response to variations in a driving current density. Both LEDs and LED systems are desirably fabricated in a single crystal GaN material system, also referred to as a monolithic system in examples herein, based on common processing of the GaN. Single crystal is defined herein as an ordered arrangement of atoms forming a single wurtzite crystal. The LEDs and LED systems include an n-type region, a p-type region with an optional electron blocking layer (EBL), and a multiple quantum well (MQW) region formed between the n-type region and the p-type region. The MQW region includes parallel layers, each alloyed with a percentage of Indium to enable a range of light emission between 400 and 600 nm. The MQW region is formed over a first active doped layer or region that is selectively patterned along one surface with depressions of one or more shapes and with one or more spacing configurations to promote controlled color emissions in MQW layers of a MQW region. Each of the one or more portions of the MQW layers of a MQW region that conform to the depressions in the first active doped layer has a lower concentration of the alloyed percentage of the Indium than other portions of the MQW layers of the MQW region. Transition regions between areas conforming to depressions in the first active doped layer and other portions of the MQW layers have a higher concentration of the alloyed percentage of the Indium than areas conforming to depressions in the first active layer, which decreases with distance from the one or more such depressions.

A method for making a color-tunable LED system, configured to emit a variety of peak wavelengths of light in response to variations in the driving current density, includes forming a first active doped n-type or p-type layer. In various examples, this first active doped n-type or p-type layer may be etched or otherwise patterned to create a variety of depressions of various shapes, sizes, sidewall angles or other characteristics and spacing configurations as referred to elsewhere herein. A MQW region is grown on the first active doped n-type or p-type layer. The MQW region includes parallel layers, each alloyed with a percentage of Indium to enable a range of light emission between 400 and 600 nm, with the layers of the MQW region conforming to one or more of the shaped depressions formed within the first active doped layer. Portions of the parallel layers conforming to depressions patterned in the first active doped layer have a lower concentration of the alloyed percentage of the Indium than the other portions of the parallel layers. Transition regions between the portion of the parallel layers conforming to the depressions in the first active layer and other portions of the parallel layers have a higher concentration of the alloyed percentage of the Indium, which decreases with distance from the portions of the parallel layers conforming to the depressions. A second active doped layer that is of opposite charge to the first active layer is grown on the MQW region.

With examples of this technology, each color-tunable LED can function as one pixel element, with each such LED capable of rapidly switching, in response to correspondingly rapid changes in driving current density, between two or more wavelengths of emission such that a single color is perceived by the eye. Individual pixels elements can be arrayed many times to create a full display system for any desired shape or resolution. A plurality of color-tunable LEDs can be combined and arrayed to form a complete, optionally monolithic LED display system. With other examples of this technology, a functioning pixel element can optionally comprise more than one monolithic color-tunable LED, each with the same or different density or design of depressions patterned in the first active doped layer and capable of emitting visible light as a variety of colors or a fixed color.

In other examples, the color-tunable LED may have additional components added to create the basis of a pixel element. The additional components can take the form of device elements, such as transistors, capacitors, and diodes by way of example. The device elements, together with the color-tunable LEDs, may be electrically connected to form a variety of circuits, by way of example, current sources and active-matrix circuits for each pixel element. The pixel elements may function by having each color-tunable LED rapidly switch, in response to correspondingly rapid changes in driving current density, between two or more wavelengths of emission such that a single color is perceived by the eye. Individual pixel elements can be arrayed many times to create a full color-tunable LED display system of any desired shape or resolution.

In examples where the color-tunable LED is included in a pixel element, additional circuitry may be integrated to feed in voltage and current signals to drive the LED arrays and together comprise an LED display system. The circuitry may take the form of external chips or be integrated on-chip with the LED to create an optionally monolithic LED display system.

Color tunable LEDs and color-tunable LED display systems as described and claimed herein provide a number of advantages and can be effectively utilized in a number of different applications, such as micro displays and larger format displays, commercial lighting, light-based data communications, and more. In particular, examples of this technology provide color-tunable LEDs that can emit light across the visible spectrum without requiring any added color converters. This reduces complexity, offers better performance, and lowers cost for many applications. Monolithic is defined for some examples herein as a common InGaN/GaN, III-N, material system used exclusively within the same wafer. Variations in examples of this technology are further able to provide monolithic color-tunable LEDs without Eu doping, use of a porous GaN substrate, or nanowire growth. Further, in other examples, single LEDs can be configured to function as a pixel, rather than the use of three LEDs to emit, selectively, red, green, and blue light, the common RGB approach used broadly today. Reducing the number of LED subpixels employed to form pixels increases potential display resolution and reduces the footprint. This smaller footprint is a particular advantage in u-LED displays intended for near eye applications such as virtual or augmented reality. It also lowers cost and enables more efficient manufacturing.

Further, the problems discussed in the background can be addressed by using an alternative method to realize a simpler system, in some examples using a monolithic, i.e. universal and common single crystalline material system, such as single crystal GaN, in fabricating LED elements/systems. Monolithic is defined herein as a common InGaN/GaN, III-N, material system used exclusively for all semiconductor growth on the same wafer. III-N is defined herein as the class of materials including GaN and elements alloyed with GaN, such as Indium or Aluminum.

In other alternative embodiments, emission driving schemes are described that may be used to ameliorate and/or abate certain undesirable visual artifacts, such as color break-up (among others).

In other alternative embodiments, design and manufacture of a LED elements/systems may incorporate a tailoring of the quantum wells to further optimize light emission. For merely one example, the quantum wells are independently configured to emit a wider range in the green and blue-in order to affect a wide-color gamut display, as discussed further herein below.

### BRIEF DESCRIPTION OF THE DRAWINGS

FIG. 1A is a cross-sectional image of an example of patterned depressions formed along one surface of a first active doped layer (n-type material in the example) prior to forming the final layers;

FIG. 1B is a bird's eye image of a section of FIG. 1A showing the different shaped depressions patterned along one surface of the first active doped layer (n-type in the example) with the edges shown and a dashed lined to symbolize the cross section for FIG. 1A;

FIG. 1C is a cross-section image of an example of a color-tunable LED system of FIG. 1B incorporating a first active doped layer (n-type material in the example) patterned along one surface with depressions of multiple shapes and spacings that promote controlled color emissions in the MQW layers of the MQW region of the LED;

FIG. 2 shows a graph of the CIE 1931 that depicts the wider color gamut of the LED display as made with the independent optimization of the individual quantum wells;

FIG. 3 is a graph of an example illustrating how a single color-tunable LED can be driven with different current densities to produce different colors of equal intensities by varying the duty cycle and current;

FIGS. 4A and 4B are graphs of an example showcasing operation of a single color-tunable LED being driven to produce a purple color as perceived by the eye by rapidly alternating between pulsed current densities that produce emission of red and blue wavelengths;

FIGS. 5A and 5B are graphs of an example showcasing operation of a single color-tunable LED being driven to produce white light as perceived by the eye by rapidly alternating between pulsed current densities that produce emission of yellow and blue wavelengths;

FIG. 6A shows a top view of an array of light emitting diode elements, as may be made and/or manufactured in accordance with any of the displays described herein;

FIG. 6B shows the array of light emitting diode elements of FIG. 5A emitting a spatially dithered pattern of two colors;

FIG. 6C shows the array of light emitting diode elements emitting a spatially dithered pattern of two colors with the opposite assignment as shown in FIG. 5B;

FIG. 7 is a graph of an example illustrating how a single color-tunable LED can be driven with different current densities to produce different colors of equal intensities by varying the duty cycle and current;

FIG. 8A is a graph of the CIE 1931 color space, of examples showcasing operation of a single color-tunable LED being driven to produce a single color as perceived by the eye by rapidly alternating between pulsed current densities that produce emission of metameric pairs of wavelengths;

FIG. 8B is a graph of the CIE 1931 color space showing a line of colors that can be reproduced using metamer pairs with equal brightness;

FIG. 8C is a graph of the CEI 1931 color space showing the color gamut of a display system using an array of color tunable uLEDs and combined with an array of fixed color uLEDs;

FIG. 9A is a top-level block diagram of a micro-LED display system;

FIG. 9B is a diagram of a micro-LED pixel element w/current and pulse width modulation control;

FIG. 9C is a diagram of a metamer selection block;

FIG. 10 shows an array of light emitting diode elements;

FIG. 11 is a top-level block diagram of a micro-LED display system;

FIG. 12 shows an array of light emitting diode elements;

FIG. 13 is a top-level block diagram of a micro-LED display system;

### DETAILED DESCRIPTION

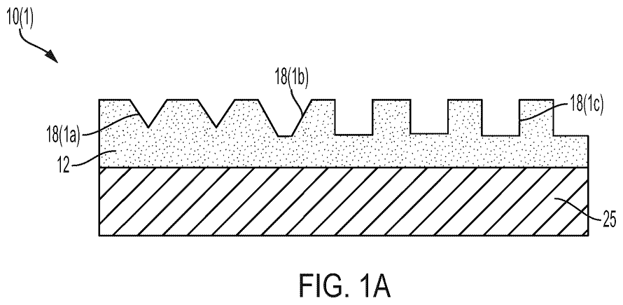

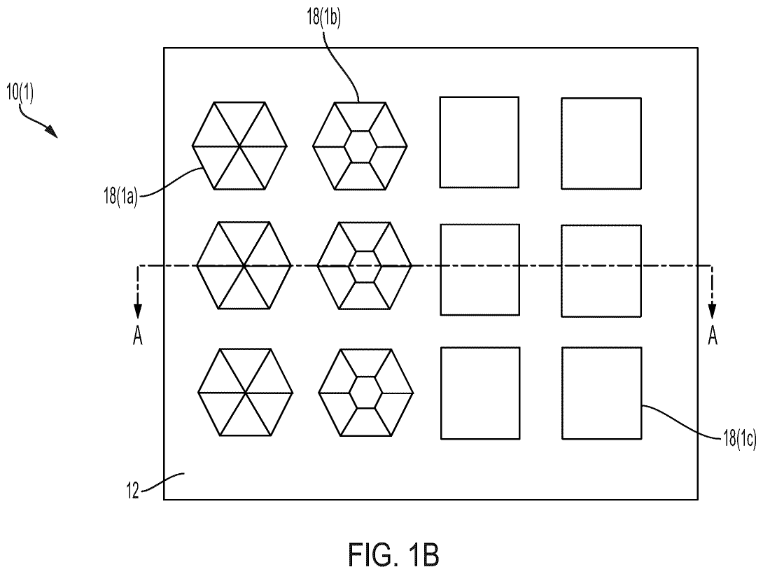

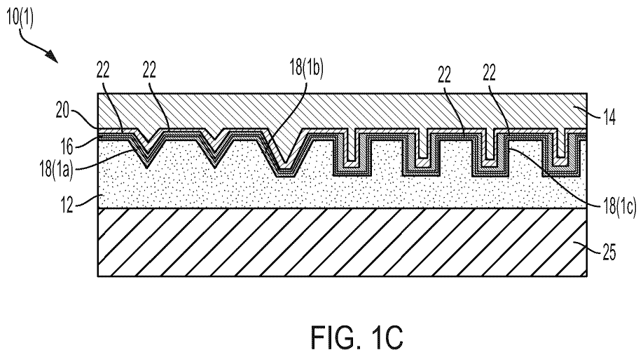

Examples of the color-tunable LED technology, as illustrated in FIGS. 1A, 1B and 1C, provides several advantages including providing a color-tunable LED system which can be effectively utilized in several different applications, such as displays, commercial lighting, communications, and more, and can optionally be made with a single material system.

Referring more specifically to FIG. 1A, in this example to create a color-tunable LED system 10(1) a patterned first doped active layer comprising an n-GaN layer is formed on an initial growth substrate 25, such as silicon or sapphire by way of example, although other types and/or numbers of doped layers and/or substrates may be used. The surface of the first active layer 12 is in this example patterned with shaped depressions 18(1a-1c), such as outer periphery or cross-sectional shapes comprising circles, triangles, squares, pentagons, hexagons, or arrangements made of multiple such shapes, with top surface diameters from about 150 nm to about 10 μm, spacings between the depressions 18(1a-1c) of about 150 nm to about 10 μm, and height or depth differences from the surface of the depressions 18(1a-1c) less than about 5 μm to enable the color-tunable emission in the MQW region, although other patterns, with other sizes, spacing, and/or shapes may be used. The side walls of the depressions 18(1a-1c) can be at angle with reference to the substrate between 0 to 90 degrees in some examples and between 90 to 180 degrees in other examples. The sidewalls of the depressions 18(1a-1c) can have positive, negative, or perpendicular sloped sidewalls with respect to the growth substrate 25. The depressions 18(1a-1c) are added for the purposes of tailoring the Indium content to control the emission spectrum from LEDs due to the differences in Indium incorporation along different crystal planes. These depressions 18(1a-1c) locally relax the crystal structure, modifying the Indium absorption within the MQW region. Use of a shaped depression 18(1c) which has a 90-degree angle relative to the substrate is expected to enhance short wavelength, blue, emission from the color-tunable LED system 10(1). While use of a positive sloped shaped depression 18(1a-b) or negative sloped shaped depression less than or greater than 90 degrees in reference to the substrate, respectively, can promote longer wavelength, red, emission from the color-tunable LED system 10(1). Selective incorporations of different shaped depressions 18(1a-1c) can be used to tailor the color emission from the color-tunable LED system 10(1) at a fixed current density.

The geometry and placement of the depressions 18(1a-1c) shown in FIG. 1A can be formed through common semiconductor process steps, such as epitaxial overgrowth, dry etching, or wet etching by way of example. These process steps are done on the first doped active layer 12, which is the first layer being electrically active in the device. Formation of the depressions 18(1a-1c) is done prior to the formation of the MQW region 16. The density and size of these selectively formed shaped depressions 18(1a-1c) can be advantageously tuned for the purposes of modifying the Indium content to obtain a desired color emission spectrum from the LEDs.

The arrangement of the depressions 18(1a-1c) can take the form of an array, such as a regular or hexagonal array by way of example, as shown in FIG. 1B. One or more of the same or different shaped depressions 18(1a-1c) may be incorporated into a single LED. The depressions 18(1a-1c) can take shape as circles, triangles, squares, pentagons, hexagons, or arrangements made of multiple such shapes.

Surface treatments can be performed to clean and remove possible surface damage after the creation of the depressions 18(1a-1c). These surface treatments may take the form of a combination of dry and wet etches or cleans.

Referring to FIG. 1C, the MQW region 16 is formed on the first doped active layer 12 and in this example includes parallel layers of GaN, alloyed with a percentage of Indium to enable a range of light emission between 400 and 600 nm. A representative percentage of Indium can be 18% by way of example. Regions of the parallel layers of the MQW region 16 that conform to the underlying depressions 18(1a-1c) have a lower concentration of the alloyed percentage of the Indium than regions of the parallel layers of the MQW region 16 not conforming to the depressions 18(1a-1c). These other regions of the parallel layers of the MQW region 16 not conforming to the depressions 18(1a-1c) are also referred herein as the planar MQWs. Additionally, in this example transition regions 22 in FIG. 1C, between the portion of the parallel layers conforming to the depressions 18(1a-1c) and the other regions of the parallel layers located outside of those conforming to the depressions 18(1a-1c) have a higher concentration of the alloyed percentage of the Indium which decreases in the other regions of the parallel MQW layers with increasing distance from the depressions 18(1a-1c).

The sides of the depressions 18(1a-1c) may be surfaces of semi-polar or non-polar crystal planes which contain less Indium due to differences in the Indium sticking coefficient during growth. The semi-polar or non-polar MQWs of the portion of the parallel layers of the MQW region 16 that are in the depressions 18(1a-1c) are also thinner than the planar MQWs or other portion of the parallel layers of the MQW region 16. The decrease of Indium in the portion of the parallel layers of the MQW region 16 conforming to the depressions 18(1a-1c), relative to the designed planar MQWs 16, is accompanied by an Indium rich “region of transition” or transition region 22 formed in MQWs of the MQW region 16 adjacent to the depressions 18(1a-1c). Indium concentration is highest at the periphery of a depression 18(1a-1c) and declines with distance from the depression 18(1a-1c) to the level of Indium alloying originally incorporated in the designed planar MQWs.

In this example, whereas the Indium poor semi-polar or non-polar MQWs of the MQW region 16 inside the depression 18(1a-1c) may have 5-15% Indium, the planar MQWs of the MQW region 16 in each of the transition regions 22 nearest the depression 18(1a-1c) have Indium concentrations as high as 30-50%, declining in concentration to the designed 18% Indium in the other portion of the parallel layers of the MQW region 18 with increasing distance from the depression 18(1a-1c). This localized increase of Indium is not detrimental to electron-hole recombination efficiency, as is the case with intentionally high Indium content growth for continuous planar MQWs, as these localized increased regions are strain relaxed due to the depression 18(1a-1c).

The second active doped layer of opposite charge type is formed on the MQW region 16, in this example the second active doped layer is a p-type AlGaN EBL layer 20 with a layer of p-type GaN 14, although other types and/or numbers of layers may be used and the EBL layer is optional in some examples. The EBL layer 20 is a p-type AlGaN layer and is located over the portion of the parallel layers conforming to all shaped depression 18(1a-1c) and on the other regions of the parallel layers outside of the shaped depressions 18(1a-1c). By way of example, the p-type EBL 20 (FIG. 1C), referred to in more detail below, could be a 5% Aluminum containing p-AlGaN layer, although other types and/or numbers of electron blocking layers can be used. The p-GaN layer 14 is formed subsequently on the p-type EBL 20, although other types and/or numbers of layers may be formed. When the higher temperature p-GaN 14 is grown on top, the higher surface mobility leads to the depressions 18(1a-1c) filling in as shown in the example in FIG. 1C.

In the final structure the shaped depressions 18(1a-1c) are located adjacent to and between these two opposite charge regions, first and second active layers 12 and 14, and where recombination of these charges happens in the InGaN layers of the MQW region 16 to produce light. The depressions 18(1a-1c) facilitate a way to easily inject charges into the InGaN layers of the MQW region 16, particularly at low currents. Combined with the mechanism that the depressions 18(1a-1c) modify the Indium content in each Indium Gallium Nitride (InGaN) layer in the MQW region 16 in or around each depression 18(1a-1c). The charges preferentially recombine initially in the Indium rich areas, leading to longer wavelength emission.

Once the layer structure of a color-tunable LED system 10(1) is grown, LEDs or other optoelectronic devices can, for example, be conventionally fabricated. For LED formation, patterning specific areas can be done with photolithography for example, where photoresist acts as a mask. Dry etching can then be used to selective remove the p-type layer 14, the EBL 20, and MQW region 16, where there is no photoresist, to then access the first active layer of n-type GaN 12. The etching process forms the individual LED structures. Additionally, a top metal or other conductor (not shown) can be deposited on the p-type GaN layer 14, forming the anode. Followed by another metal layer or other conductor (not shown) deposited on the n-type GaN layer 12 which can be utilized as the cathode.

Color-tunable LEDs and LED Systems, optionally a common, single crystalline material system also referred to as monolithic, made in accordance with examples of this technology produce a range of desired color emissions from ~640 nm down to ~425 nm, spanning the visible spectrum. The color-tunable LED system as represented in FIG. 1C illustrates one example of this technology. In this example, low current density applied to the color-tunable LED system 10(1) produces red emission. Emission is significantly blue-shifted with increasing current density. Accordingly, this causes the colors to change from red to orange, to yellow, to green, and then to blue. For smaller LEDs the color emission change uses lower current compared to larger LEDs, as smaller LEDs will have a greater current density at the same applied current as larger LEDs. By way of example, for a 35 μm color-tunable LED the current density ranges from ~6×10⁵ to ~8*10-2 mA/μm² for red and blue respectively.

The emission range of color-tunable LEDs and LED systems as described herein can be tuned to emit longer or shorter wavelengths as a function of the planar Indium percentage utilized. Increased Indium percentage, such as from 18% to 25% in the planar MQWs of the MQW region 16 increases the inclusion of Indium in the semi-polar or non-polar MQWs of the portion of the MQW region 16 in the depressions 18(1a-1c), as well as the localized Indium composition in the planar MQW near to the depressions 18(1a-1c). This shifts the total range of optical wavelengths able to be generated from one of the color-tunable LED systems 10(1) to longer wavelengths at both low and high current densities. In contrast, if the designed planar MQW Indium percentage of the MQW region 16 is decreased, such as from 18% to 15%, depression 18(1a-1c) and the region of transition 22 which have incorporation at the same density would similarly shift the range of wavelengths generated to shorter values at both low and high current densities. Where less Indium is incorporated into the semi-polar or non-polar MQWs of the portion of the MQW region 16 in the depressions 18(1a-1c), the corresponding Indium rich regions of transition regions 22 of the MQW region 16 also contain less Indium.

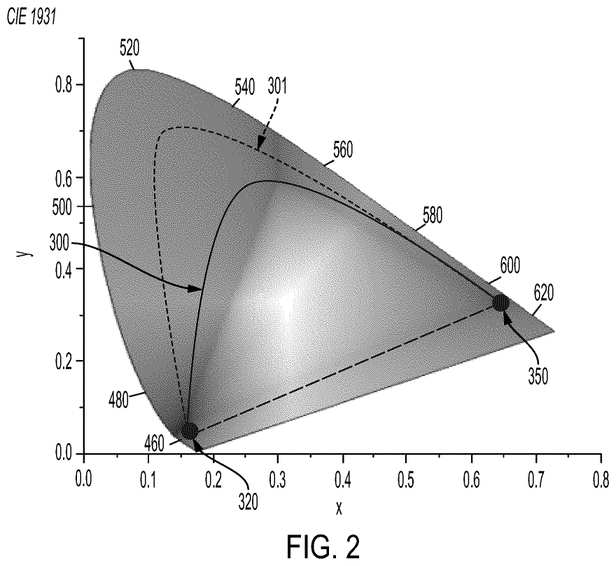

As well as designing substantially three regions with defined percentages of Indium, it may be desirable to modify some of the MQW layers with a different percentage of Indium, effectively creating four or more regions tuned to desired wavelength emission, so as to influence the curve of the range of colors reproducible, emitted by the LED with changes in current density. For example, in one embodiment, reducing the Indium in the deeper, lower, layers of the horizontal MQW layers may shift the emitted color curve 301 toward the emerald green as shown in FIG. 2, expanding the color gamut.

Beyond engineering the geometry and number of shaped depressions 18(1a-1c) contained within each color-tunable LED system 10(1) to modify light emission, there are other techniques which may be used in conjunction to or independent of. For example, each individual quantum well in the MQW region 16 may be designed to have a unique concentration of Indium. The unique concentration of Indium in each quantum well in the MQW region 16 will modify the emission of light. In general, for conventional LEDs, the quantum well in the MQW region 16 which are located nearest to the second doped region 14 will dominate light emission at low applied current densities, whereas the quantum wells located closer to the first doped region 12 will only contribute at high current densities.

Though in a color-tunable LED system 10(1) the shaped depressions 18(1a-1c) interrupt the planar MQW region 16, where the semi-polar or non-polar MQWs of the portion of the parallel layers of the MQW region 16 that are in the depressions 18(1a-1c) are thinner and have a lower Indium concentration, while a transition region 22 is formed in the MQWs of the MQW region 16 adjacent to the shaped depression 18(1a-1c) with increased Indium concentration. At low applied current density, carrier injection is dominated by the lateral injection from the shaped depression 18(1a-1c) into the transition region 22 with the higher Indium content. With increases in applied biases and corresponding current density, the light generated is dominated by the vertical injection into the planar MQWs 16 away from shaped depression 18(1a-1c) and the region of transition to produce light of shorter wavelength emission. At still higher current densities, further energy band bending, population of excited states in the quantum wells, and population of the MQWs 16 which conform to the shaped depressions 18(1a-1c) occurs to produce even shorter wavelength emission. Based on the methods of current injection, engineering the Indium content in each MQW of the MQW region 16 can be very useful for engineering the emission range, particularly at moderate or high injection currents. There will be a weaker dependance on the vertical distance of each quantum well in the MQW region 16 for emissions at low current density, due to the lateral current injection mechanism.

Tuning the Indium content of each MQW in the MQW region 16 can be advantageous applied to better engineer green and blue emission, enhancing and/or widening coverage of the observable color space as shown in FIG. 2. In an exemplary embodiment the quantum wells nearest to the second doped region 14 would retain a nominal amount of Indium such that the region of transition 22 near the shaped depression 18(1a-1c) produces a desired increased Indium concentration for the chosen long wavelength of emission. Quantum wells in the MQW region 16 positioned further from the second doped region 14 would have a lower amount of Indium between 1-15% less, compared to the quantum wells nearest to the second doped region 14. The quantum wells with the lower amount of Indium further from the second doped region 14 would boost the shorter wavelength emission, such as in green and then blue, as the vertical current injection dominates at higher current densities.

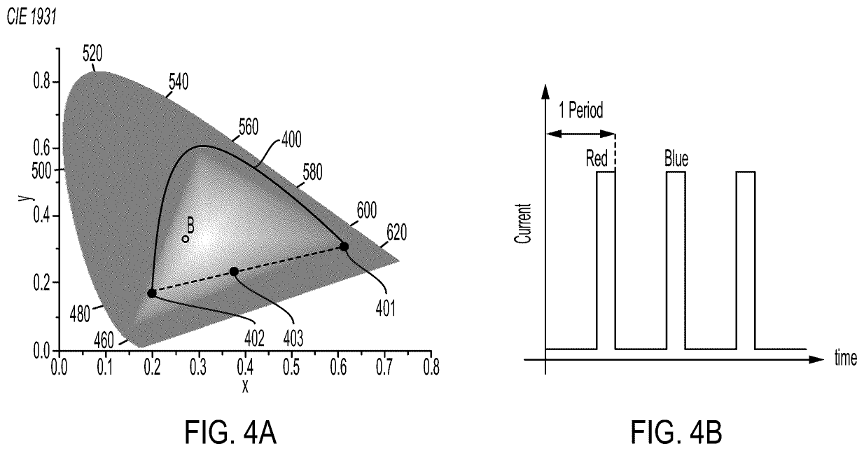

It will be appreciated that the wide color gamut of FIG. 2 may be applied to any and/or all of the gamuts discussed herein. In particular, the gamuts of FIGS. 4, 5, 8A-C may be widened (e.g., in the green and/or blue region) per the methods, techniques and systems discussed herein to create such a display.

Application of the independent optimization of the quantum wells in the MQW region 16 to engineer greater blue emission would increase parabolic coverage of the color gamut from an unoptimized coverage 300 to an increased optimized coverage 301 in the green and blue space.

A color-tunable LED system 10(1) which makes use individually optimized quantum wells in the MQW region 16 can be similarly formed through selective area growth or selective etching which is followed by surface treatments and regrowth of the MQW region 16 and the second doped region 14. Alternatively, a stain engineered buffer layer below the MQW region 16 can be engineered such V-groove or V-pit shaped depression 18(1a) are nucleated on existing threading dislocations and form during the MQW region 16 growth.

In one method of operating an LED in one of the exemplary color-tunable LED systems such as illustrated in FIG. 1C, a positive bias is applied to the anode, while the cathode is held at ground. Alternatively, the cathode can be held at a negative bias, with respect to a grounded p-type contact. Application of such bias injects holes from the p-type GaN region 14 into the MQWs in the MQW region 16 to recombine with electrons and produce light. However, before this occurs the holes should first overcome an energy barrier in some examples provided by the optional EBL (electron blocking layer) 20. Use of the EBL 20 between the p-type GaN layer 14 and the MQW region 16 creates a large barrier for electrons while creating a smaller barrier for holes. The semi-polar or non-polar planes of the depressions 18(1a-1c) in one of the exemplary engineered color-tunable LED system 10(1) have reduced internal piezoelectric fields which lessens the barrier to holes provided by the EBL 20. Thereby, holes (h+) are more easily able to be injected laterally into the Indium rich MQWs rather than vertically to produce a longer wavelength such as emitting the color red. As the current density further increases the holes are able to be injected vertically, populating the planar MQWs located away from each depression 18(1a-1c) producing a shorter wavelength color such as green. Increasing the current density further leads to continued band bending, combined with hole population of the thin MQWs in each depression 18(1a-1c) producing an even shorter wavelength of light, such a blue. Through these mechanisms, current driven color-tunable emission is achieved.

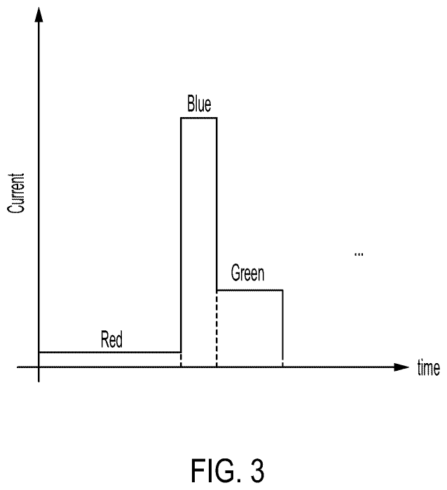

Leveraging the current controlled color tunability of the color-tunable LED system 10(1), pulsed current driving schemes can be advantageously used. Control over the duty-cycle and current level of the applied current can provide brightness control for each monolithic color-tunable LED system 10(1). To yield equal color brightness, red will have the highest duty cycle of the colors with a low current density. Blue, which operates at high current density, will have the lowest duty cycle of the colors. In-between colors will operate at current and duty-cycles bounded by red and blue. The driving differences of red, blue, and green for equal brightness are shown graphically in FIG. 3, though not to scale. Tuning the duty-cycle and current density for each wavelength makes the viewed intensity appear as the same for each color, as the eye or detectors integrate over the period. The applied current during a period can take many forms including, but not limited to, a square wave, sine wave, or ramp.

Making use of a tuned duty-cycle and current density for each desired emission wavelength/color, observed full color emission from the color-tunable LEDs in LED system 10(1) and LED display system pixels can be realized. Conventionally, three LEDs are used to form a pixel, where each LED emits either red, green, or blue. Uniquely enabled by color-tunable LEDs made in accordance with examples of this technology, the number of individual LEDs used for a pixel can be reduced to as few as one. One or more color-tunable LEDs systems 10(1) can be driven such that, in each period of the duty-cycle, multiple pulsed wavelengths are emitted such that a single observed color is perceived by the eye. Examples of such an approach can include the emission of red and blue during a single period to emit purple or pink due to the properties of color mixing, FIGS. 4A and 4B.

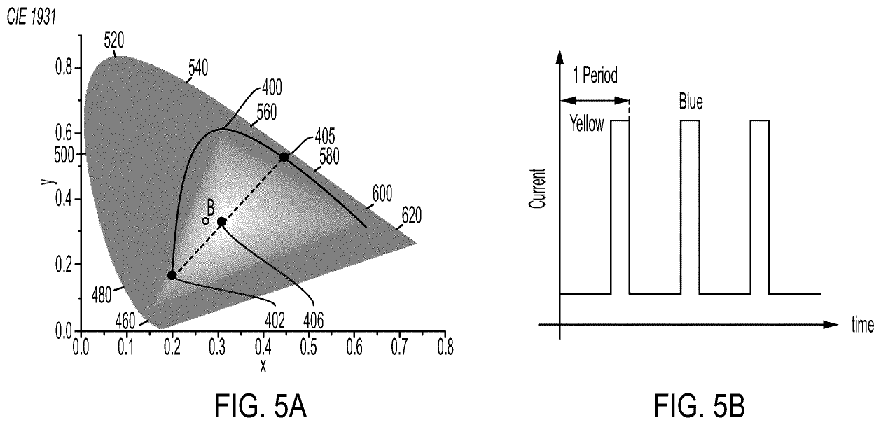

The gamut 400 represents the range of single emission wavelengths/colors. The current density duration of red (401) and blue (402) controls the weight of each wavelength to determine the color of emission (403) during the period. A larger blue current density duration than what is used to balance the intensity with red will emit purple. A larger red current density duration than what is used to balance the intensity with blue will emit pink. Similar principles can be used between green and red wavelengths to emit shades of yellow/orange, or blue and green wavelengths for shades of cyan. Mixing of blue (402) and yellow (405) wavelengths can be leveraged as in conventional lighting to yield emitted white light (406) as seen by the observer, as illustrated in FIGS. 5A and 5B. Wavelength mixing to produce different colors for a single period is possible using the color-tunable LED systems 10(1), allowing a single LED to act as a pixel. Instead of fixed operating points of red, green, and blue, the color tunability of a color-tunable LED system 10(1) can, using rapidly changing current in a single period, to produce any color. This enables one LED to function as a single, full color capable, pixel element.

Having the color-tunable LED system 10(1) function as a single pixel element can be realized in a variety of display architectures. By way of example, a passive matrix in which the pixel elements are arrayed together to constitute a display system can be formed. Furthermore, additional device elements can be included with the color-tunable LED system 10(1) to form the basis of a pixel element. An example of this is a transistor integrated with a color-tunable LED system 10(1) to form the basis of a pixel element, though many other device elements such as additional transistors, resistors, and capacitors may also be integrated. These pixel elements which include device elements may similarly be arrayed to form an LED display system, such as device elements comprising transistors which are electrically connected to the LED to control its operational states, including on-off, brightness, etc. If transistors or other device elements connected to the LED in an LED display system use the same material system as the LED, the display system in these examples comprises a common, single crystalline material or monolithic color tunable LED display system. Pixel elements which are arrayed to form display systems may additionally be integrated with additional circuitry, such as driving circuitry to supply voltage and current to the array by way of example. This additional driving circuitry can take the form of external chips and circuits or may take the form of circuitry which is monolithically integrated into a common, single crystalline material with the color-tunable LEDs.

Accordingly, as illustrated and described by way of the examples herein, examples of this technology provide color-tunable, optionally common, single crystalline material or monolithic LED systems and LED display systems, which may be effectively utilized in a number of different applications, such as displays, commercial lighting, communications, and more. In particular, examples of this technology provide the integration of color-tunable LEDs without requiring color converters. This capability reduces LED system complexity and offers better performance for increased brightness and efficiency. Examples of this technology are able to provide color-tunable LEDs without Eu doping, use of a porous GaN substrate, or nanowire growth.

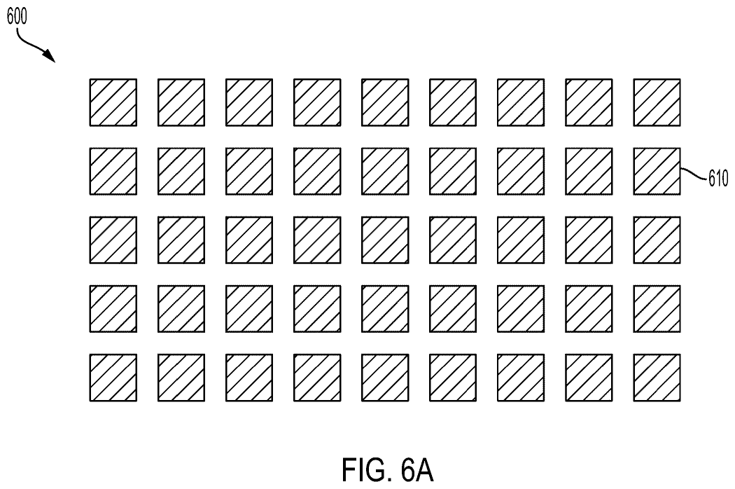

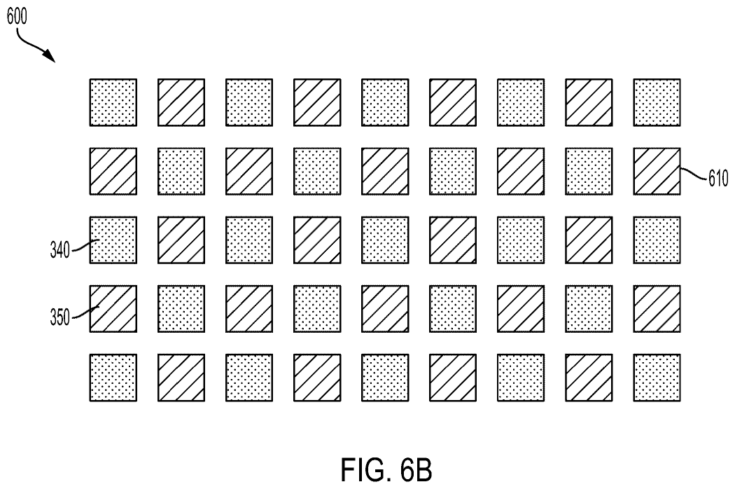

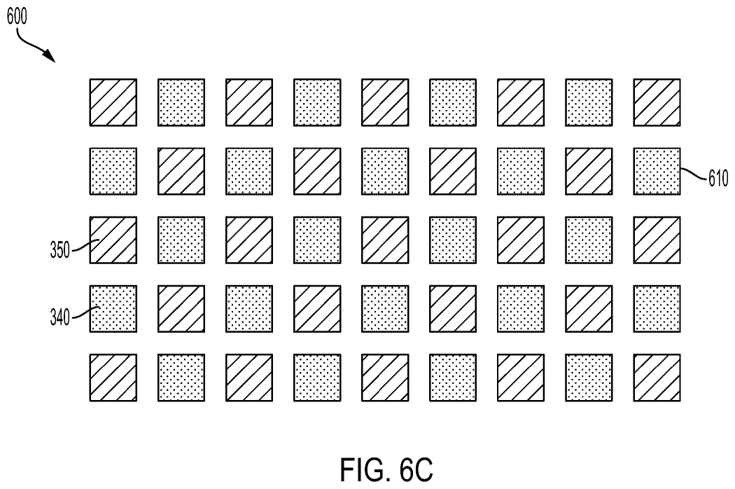

As with examples of the embodiments described herein, each color-tunable LED may function as one pixel element, with each such LED capable of rapidly switching, in response to correspondingly rapid changes in driving current density, between two or more wavelengths of emission such that a single color is perceived by the eye. Individual light emitting diode pixel elements can be arrayed many times to create a full display system for any desired shape or resolution as shown in FIG. 6A. A plurality of color-tunable LEDs can be combined and arrayed to form a complete, optionally monolithic LED display system. With other examples of this technology, a functioning pixel element can optionally comprise more than one monolithic color-tunable LED, each with the same or different density or design of shaped depressions 18(1a-1c) patterned in the first active doped layer 12 and capable of emitting visible light as a variety of colors or a fixed color.

In other examples, the color-tunable LED may have additional components added to create the basis of a pixel element. The additional components can take the form of device elements, such as transistors, capacitors, and diodes by way of example. The device elements, together with the color-tunable LED systems 10(1), may be electrically connected to form a variety of circuits, by way of example, current sources and active-matrix circuits for each pixel element. The pixel elements may function by having each color-tunable LED system 10(1) rapidly switch, in response to correspondingly rapid changes in driving current density, between two or more wavelengths of emission such that a single color is perceived by the eye. Individual pixel elements can be arrayed many times to create a full color-tunable LED display system of any desired shape or resolution.

In examples where the color-tunable LED system 10(1) is included in a pixel element, additional circuitry may be integrated to feed in voltage and current signals to drive the LED arrays and together comprise an LED display system. The circuitry may take the form of external chips or be integrated on-chip with the LED to create an optionally monolithic LED display system.

Color tunable LED systems 10(1) and color-tunable LED display systems as described and claimed herein provide a number of advantages and can be effectively utilized in a number of different applications, such as micro displays and larger format displays, commercial lighting, light-based data communications, and more. In particular, examples of this technology provide color-tunable LEDs that can emit light across the visible spectrum without requiring any added color converters. This reduces complexity, offers better performance, and lowers cost for many applications.

Further, in other examples, single color tunable LED systems 10(1) can be configured to function as a pixel, the center of luminance, either alone, or in shared combination with neighboring subpixels, rather than the use of three LEDs to emit, selectively, red, green, and blue light, the common RGB approach used broadly today. Reducing the number of LED subpixels used to form pixels increases potential display resolution and reduces the footprint. This smaller footprint is a particular advantage in u-LED displays intended for near eye applications such as virtual or augmented reality. It also lowers cost and enables more efficient manufacturing.

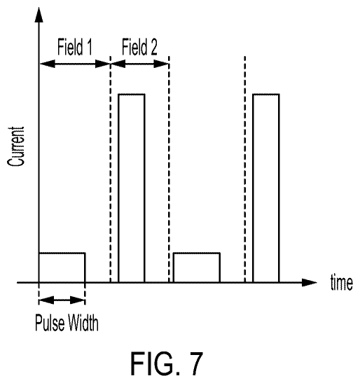

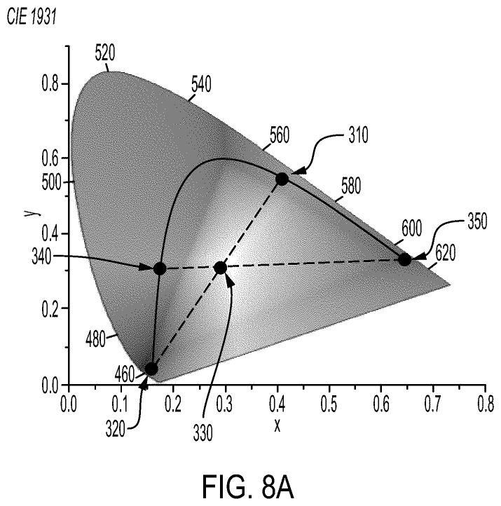

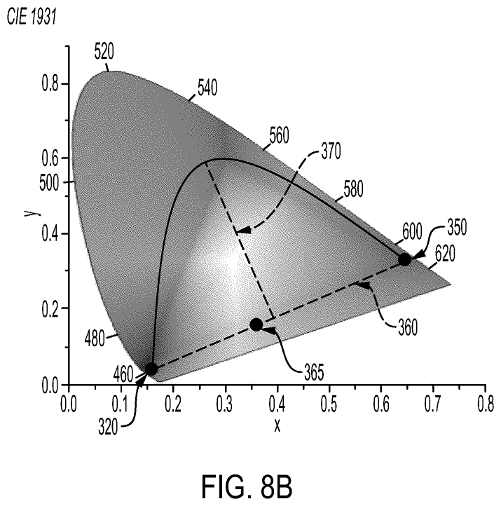

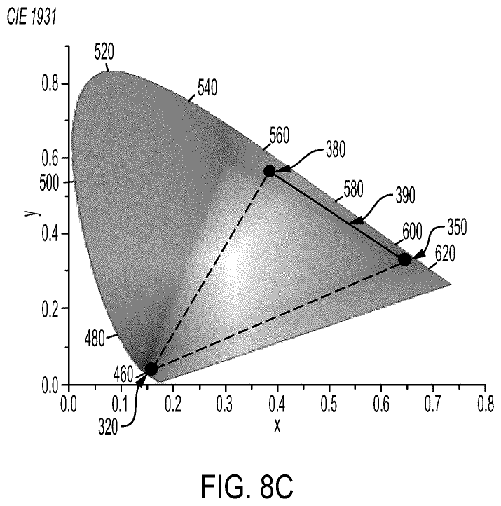

As shown in FIG. 6A, a plurality of color tunable light emitting diode (LED) elements 610 may be arranged in an array 600 to form an image reconstruction and color reproduction electronic display according to one embodiment of the present application. Each LED may be tuned to emit a given color from a range of colors. This color tunability is enabled by the current density, as was more fully explained in the US 2022/0367754 A1 application—and is incorporated herein in its entirety. For example, a first color 310(with reference to FIG. 8A) may be selected and emitted at an exemplary LED element, such as 610 in FIG. 6A. This LED element 610 may then be tuned to a second (or more) color 320 in another period of time. If this other color(s) is switched back to the first color and then back to the other color rapidly, the Human Vision System (HVS) will perceive this as a combined color 330. This process is well known in the art as Field Sequential Color (FSC). In this embodiment a first Field 1 is alternated with a second Field 2 in a repeating fashion over time as illustrated in FIG. 7. In several embodiments, varying the application of current over time may be set at a frequency that is greater than 48 Hz. Such a rate tends to correspond with the flicker fusion frequency of the HVS.

The color of the LED 610 is set by the current by the process taught in Application US 2022/0367754 A1. The brightness (that is, energy emitted) is set by the Pulse Width. This second process also is well known in the art as Pulse Width Modulation. The combination of these two processes may be applied in a novel fashion to these LED displays disclosed herein and in the co-owned Application US 2022/0367754 A1. Since the temporally mixed (FSC) color point 330 may be reproduced with other emitted color points 340 and 350, there are a range of other color combinations, known in the art as metamers. In FIG. 8A, the metamers for the color point 330 are those colors that lie on the available range of emittable colors 300 between the first color 310 and the second color 350 on one side of the color arc 300 while their metameric companion colors lie on the other side of the color arc 300 between a first color 320 and second color 340. This means that that in theory there are an infinite number of metameric combinations for each color point 330. In practice, in digitally quantized systems, there will be a finite number available, depending upon the bit depth of the limiting function block.

A problem well known in the art of FSC is a phenomenon known as Color Break-Up, often presenting as “rainbow edges”. Color Break-Up occurs when the viewer's gaze moves across the screen and colors no longer are fused together. Various solutions have been sought by previous practitioners. The most common practice is to increase the field rate. The downside of this method is power consumption increases with the rate. A most satisfactory method is herein disclosed that takes advantage of the novel features of the present application in combination with a better understanding of the HVS.

In FIG. 6B is shown the array of LED emitters 600 of FIG. 6A with a pattern of two colors, for example a first color 340 (at a first LED emitter) and a second color 350 (at a second LED emitter) from FIG. 8A which when spatially blended together by the HVS results in the perceived color point 330. In addition (in another embodiment), it should be noted that the first LED emitter may emit color point 340 in Field 1. In the next Field 2, as shown in FIG. 6C that same LED emitter 610 may emit color point 350. Thus, there is at the single LED emitter 610 the LED is operating in Field Sequential Color (FSC) reproduction perceived by the HVS as color point 330. The combination of the spatial pattern, known in the art as a spatial dither and the FSC sequence results in a novel chromatic spatiotemporal dither pattern that robustly solves the Color Break-Up problem of FSC alone.

It should be appreciated that not all colors have a range of metamers. Some colors, those that lie along the range of single emission wavelengths/colors 300 and those that lie along the line of purples 360, for example magenta 365 as shown in FIG. 8B, have only one set of emitted colors that may blend together to reproduce the desired perceived color. Those along the range of single emission wavelengths, due to the curved nature of the range in color space, and any two non-identical emitted colors reproduces a perceived color inside of the curved boundary. Thus, the system uses the same color for both fields and pattern of the spatiotemporal dither; that is say, no dither pattern may be available (except in the mathematical sense of a degenerate pattern).

While most colors will have a range of metamers available, some metameric combinations may be more desirable in a given instantiation. For example, in some, it may be desirable to use the metamer with the lowest difference in perceived brightness so that the spatiotemporal dither pattern will appear to be smooth and even in the luminance channel of the HVS. In some instances, it may be desirable to select the metameric pair that uses the least power given that the emitted colors are controlled by the current. These differing choices may be referred to as a metamer policy.

There is a line of colors 370 to be reproduced substantially in the middle of the gamut which have the property of having equal brightness utilized when a metamer pair is selected that has substantially the same y value. For colors on either side, one emitted color would have to be brighter than the other, leading to a difference in luminance. In these colors it may be best to choose a metamer pair that when the y value multiplied by the brightness desired are substantially equal in perceived luminance. The resulting pair will then have a similar luminance, reducing chances for visible spatiotemporal artifacts.

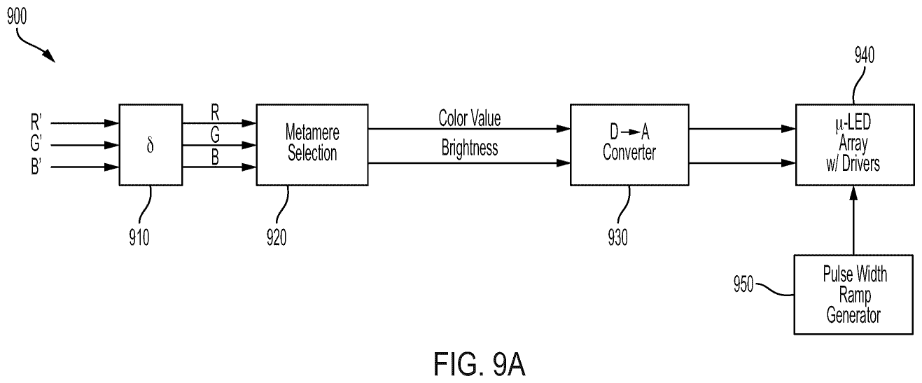

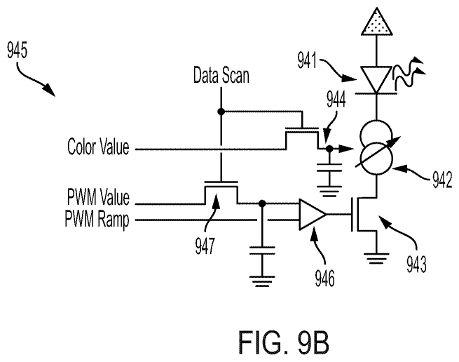

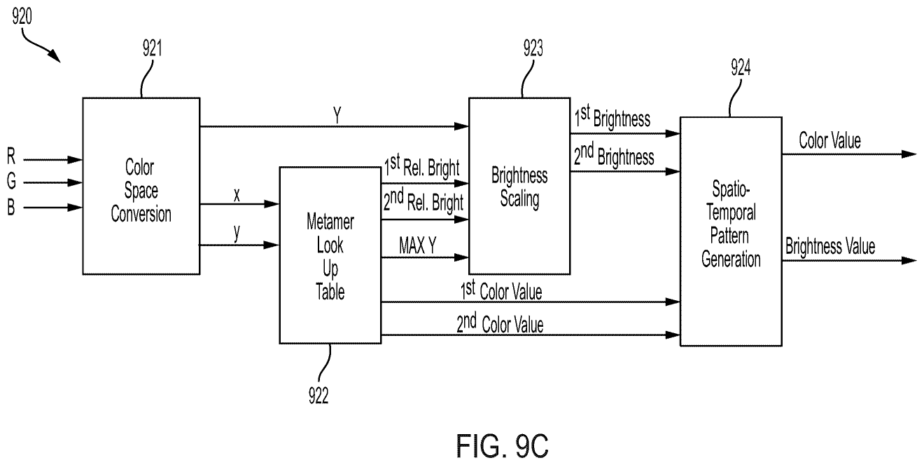

Shown in FIG. 9A is a top-level block diagram 900 of one possible embodiment of the drive electronics for a display contemplated by this application. Conventionally, displays are sent color information per pixel in a tristimulus gamma quantized digital values R*G*B*. These may be converted to linear RGB values by a gamma conversion function block 910. This may be a simple Look-Up Table (LUT) as detailed in U.S. Pat. No. 8,411,022 and incorporated herein by reference. This may be followed by a novel metamer selection function block 920.

To simplify the computational problem of metamer selection and brightness the RGB value may be converted to any of several tristimulus values known in the art wherein one of the values is the luminance, for example xyY, or a functional equivalent. The xy values are used to select the unscaled metamer pair and a relative brightness ratio between them. This relative brightness value is then further scaled by the relative brightness used to provide the desired Brightness Value given the different inherent energy emitted by the LEDs at different emitted wavelengths given the different currents used to control the color emitted. After the selection of the metamer pair, only one emitted color is selected per pixel per field. Alongside the emitted color value (i.e., the current desired) is the desired brightness value (i.e., the pulse width desired). Both of these values may be in digital form.

In one embodiment, it may be advantageous to choose the metamer policy and metameric pair choice “off-line”, that is to say, either using mathematical formula in a computer or by hand, for a selected set of colors to be reproduced. In the on-line hardware that space set of colors may be stored in a larger Look-Up Table to be used directly, or a smaller Look-Up Table (LUT) to interpolate the metamer pair between the selected pre-calculated metamers. Such an arrangement has the advantage of computational simplicity as well as making the selection from the range of metamer pairs available causal and determinable rather than the ill posed problem it otherwise would be.

The high level metamer selection block 920 in FIG. 9A is expanded in FIG. 9C. The input is linearized RGB data that is converted, transformed, to xyY color space, per methods well known in the art, by the Color Space Converter block 921. The x and y values are color coordinates of the input color on the CIE 1931 color space 300 as shown in FIG. 8A and FIG. 8B. The Y value is the luminance of that color point.

The xy color point is used as an index to the Metamer Look-Up-Table (MLUT) block 922 which outputs the Relative Brightness of the metamer pair and the maximum luminance value (Max Y) that such a color may take. The Relative Brightness of the metamer pair defines where the color will be along the line of colors that a metamer pair may reproduce. Given that the color tunable LED system 10(1) may have different light output efficiencies at different emitted colors, the Relative Brightness may also encode and compensate for this, thus the utility of having chosen metamer pairs and their associated Relative Brightness values off-line to be stored in the MLUT.block 922. The third value to be stored and retrieved is the maximum luminance (MaxY) that a color at the given xy color point may take.

The ratio of Y and Max Y of the color may then be used to scale the Relative Brightness of the two colors of the metamer pair by the Brightness Scaling block 923 as follows:

Relative Brightness X (Y/MaxY)=Brightness Value

The Color Values and the Brightness Values are passed to the Spatio-Temporal Pattern Generator block 924 which may select one color of the pair to be emitted given the field and pixel position. This may be the checkerboard of FIG. 6B and FIG. 6C or some other pattern deemed desirable in a particular instantiation of the embodiment.

The Color Value and the Brightness Value are passed to Digital-to-Analog Converters 930 shown in FIG. 9A. The color tunable micro light emitting diode (u-LED) array 940 receives and stores the analog voltages to control current and pulse width for each pixel.

Shown in FIG. 9B is an LED pixel element with its driver and control circuit 945. It should be appreciated that this is merely one schematic diagram and that those in the art will be able to design functionally equivalent circuits in other ways. The pixel element and its drive & control circuit 950 may be comprised of a micro-LED 941 in series with an adjustable constant current supply element 942 and a power switch 943. The adjustable constant current supply element 942 may be controlled by a voltage that is stored by a sample&hold circuit 944 receiving its voltage value from the Color Value signal. The power switch 943 may be controlled by a comparator circuit element 946 that compares the stored Pulse Width Modulation (PWM) Value from the sample&hold circuit 947 and the Pulse Width Modulation Ramp from the Pulse Width Ramp Generator 950. The timing of the sample&hold circuits may be controlled by the common Data Scan signal, such as for active matrix display backplanes.

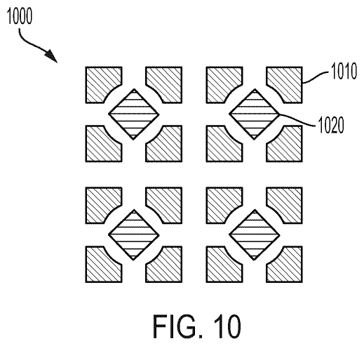

Shown in FIG. 10 is an array of u-LEDs 1000, comprising color tunable u-LED emitters 1010 in an orthogonal pattern, along with an array of fixed color u-LED emitters 1020 at a lower density. Referring to FIG. 10 and FIG. 8C showing the CIE 1931 color chart, the color tunable u-LEDs 1010 may be tunable between substantially red 350 and green 380 wavelengths, along the ‘line of yellows’ 390, while the fixed color u-LEDs 1020 may be substantially blue 320. This layout is substantially optimized for the manner in which the HVS utilizes the longer wavelengths along the right side of the CIE 1931 color diagram shown in FIG. 8C to provide high resolution luminance information. It should be appreciated that the very short wavelength blue at approximately 950 nm is poorly sampled by the eye and out of focus when longer wavelengths are in focus.

Of course, many other layouts may also be used and are contemplated in the scope of the present application.

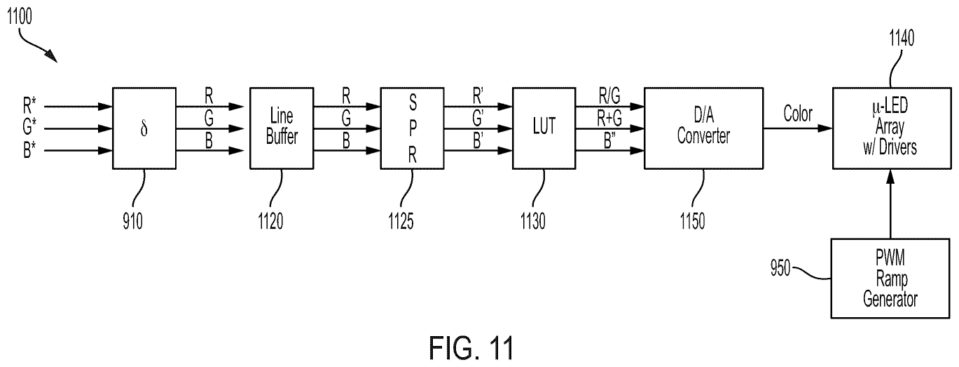

FIG. 11 shows a high-level block diagram of a display system implementing an embodiment of the current application. Gamma quantified R*G*B* tristimulus color values may be input to a gamma correction Look-Up-Table (LUT) 910 to output linear RGB values. The values are stored in Line Buffers 1120 to provide data to a SubPixel Rendering (SPR) block 1125. The SPR block 1125 utilizes SPR filters. The Blue color plane values may be filter using the following filter kernel:

| | |
|---|---|
| 0.25 | 0.25 |
| 0.25 | 0.25 |

This filter provides the average of the Blue values mapped to the surrounding color tunable u-LEDs 1010, which may not provide the blue light desired to provide full color to allow the Blue u-LEDs 1020 to provide that light.

The Red (R) and Green (G) values may optionally be modified by using the following filter kernel sampling the Blue color plane:

| | | | |
|---|---|---|---|
| −1 | −1 | −1 | (divided by 8 scaled by the luminance of blue) |
| −1 | +8 | −1 | |
| −1 | −1 | −1 | |

This value added to the Red and Green value provides a means of reconstructing the high spatial frequency luminance contribution that the Blue values would have provided if the blue μ-LED subpixels had the same density (resolution) as the color tunable μ-LEDs.

The SPR R′G′B′ data is passed to a LUT 1130 that maps the data to the values utilized by the mix of color tunable and fixed μ-LEDs of the μ-LED Array 1140. The R/G color is from the ratio of R′ to G′ specifying a given hue along the ‘line of yellows’. The R+G value is the desired brightness value as a percentage of the Pulse Width Modulation. This value takes into account not only the brightness of the combined Red (R′) and Green (G′) values, it also adjusts them based on the efficiency of the color tunable μ-LEDs 1010 at each given R/G value. The B″ value is the desired brightness value as a percentage of the Pulse Width Modulation; it also adjusts them based on the efficiency of the Blue μ-LEDs 520 at each given B″ value. The use of an LUT instead of a complex mathematical algorithm which it represents is that the LUT 1130 may be programmable for different μ-LED arrays, reducing manufacturing cost by using the same image processor design.

The digital values from the LUT 1130 are passed to a Digital-to-Analog (D/A) Converter 1150 that provides analog voltages used by the μ-LED Array's Drivers 1140.

The color tunable μ-LEDs 1010 have driver circuits like that shown in FIG. 5B and explicated above. The fixed Blue μ-LEDs 1020 may have drivers that elides the color value sample&hold circuit and provide a fixed value constant current source.

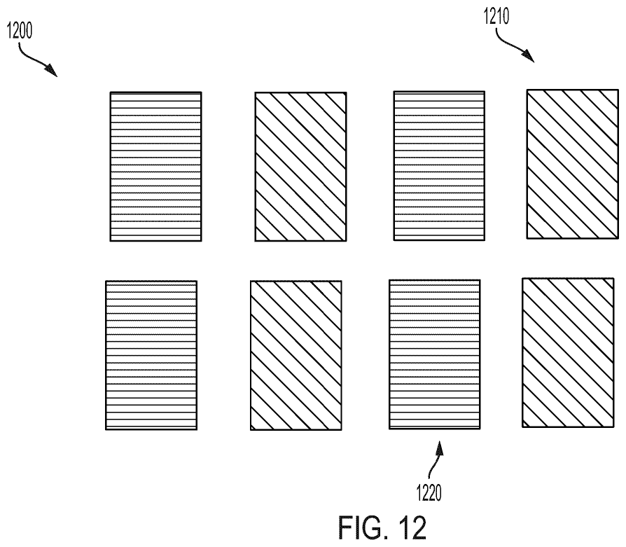

Shown in FIG. 12 is a top view of an array of μ-LEDs 1200, comprising color tunable μ-LED emitters 1210 in an orthogonal pattern, along with an array of fixed color μ-LED emitters 1220 at the same density. Referring to FIG. 12 and FIG. 8C showing the CIE 1931 color chart, the color tunable μ-LEDs 1210 may be tunable between substantially red 350 and green 380 wavelengths, along the ‘line of yellows’ 390, while the fixed color μ-LEDs 1220 may be substantially blue 320. The system provides full color reproduction and image reconstruction with two subpixels per pixel in that an incoming pixel may be mapped to a color tunable μ-LED and a neighboring fixed blue emitting μ-LED.

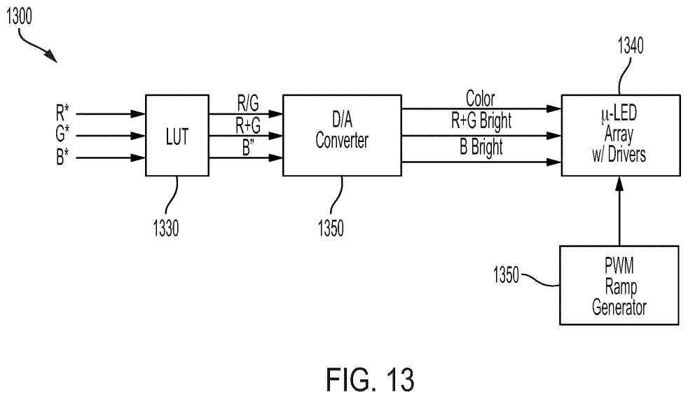

FIG. 13 shows a high level block diagram of a display system implementing an embodiment of the current application. Gamma quantified R*G*B* tristimulus color values are input to a LUT 1330 that maps the data to the values utilized by the mix of color tunable and fixed μ-LEDs of the μ-LED Array 1340. The R/G color is from the ratio of R to G specifying a given hue along the ‘line of yellows’. The R+G value is the desired brightness value as a percentage of the Pulse Width Modulation. This value takes into account not only the brightness of the combined Red (R) and Green (G) values, it also adjusts them based on the efficiency of the color tunable μ-LEDs 1210 at each given R/G value. The B″ value is the desired brightness value as a percentage of the Pulse Width Modulation; it also adjusts them based on the efficiency of the Blue μ-LEDs 1220 at each given B″ value. The use of an LUT instead of a complex mathematical algorithm which it represents is that the LUT 1330 may be programmable for different μ-LED arrays, reducing manufacturing cost by using the same image processor design.

### Enumerated Embodiments

The following enumerated embodiments are presented to illustrate certain aspects of the disclosure, and are not intended to limit its scope. The use of the word “include”, “includes” and/or “including” encompasses the meaning of all of the following: “comprise”, “comprises”, “comprising”, “consisting of”, “comprising essentially of”, and/or the like.

A first enumerated embodiment includes: an LED system able to emit a variety of peak wavelengths of light in response to variations in driving current density, the system including: one or more pixel elements that each comprise one or more LEDs each including: a first active doped layer on a substrate and selectively patterned along one surface opposite from the substrate with depressions in one or more shapes and with one or more spacing configurations to promote controlled color emissions in MQW layers of an MQW region; the MQW region formed over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers where the alloyed percentage of Indium decreases with distance from the portions of the MQW layers that conform to the depressions; and a second active doped layer formed on the MQW region that is of opposite in charge to the first active doped layer.

A second enumerated embodiment includes any of the first enumerated embodiments, further including: a transition region between each of the portions of the MQW layers conforming to the depressions and each of the other portions of the MQW layers and which transition region has a higher concentration of the alloyed percentage of Indium than the other portions of the MQW layers.

A third enumerated embodiment includes any of the first through second enumerated embodiments, further including: an electron blocking layer between the MQW region and the second active doped layer.

A fourth enumerated embodiment includes any of the first through third enumerated embodiments, further including: the depressions have an inner surface which is at angle with reference to the substrate between 0 and 90 degrees.

A fifth enumerated embodiment includes any of the first through fourth enumerated embodiments, further including: the depressions have an inner surface which is at angle with reference to the substrate between 90 and 180 degrees.

A sixth enumerated embodiment includes any of the first through fifth enumerated embodiments, further including: the depressions are spaced from each other at a distance between 150 nm and 10 μm.

A seventh enumerated embodiment includes any of the first through sixth enumerated embodiments, further including: a depth difference between each of the depressions is a less than about 5 μm.

An eighth enumerated embodiment includes any of the first through seventh enumerated embodiments, further including: the one or more shapes of the outer periphery of the depressions includes one or more circles, triangles, squares, pentagons, or hexagons.

A ninth enumerated embodiment includes any of the first through eighth enumerated embodiments, further including: the LED system is entirely formed in a common single material system.

A tenth enumerated embodiment includes any of the first through nineth enumerated embodiments, further including: one or more driving circuitry elements coupled to the each of the one or more pixel elements.

An eleventh enumerated embodiment includes any of (or none of) the first through tenth enumerated embodiments, further including: a method for making an LED system able to emit a variety of peak wavelengths of light in response to variations driving current density, the method including: forming one or more pixel elements each including one or more LEDs, wherein the forming further includes: providing a first active doped layer on a substrate; selectively patterning the first active doped layer along one surface opposite from the substrate with depressions in one or more shapes and with one or more spacing configurations to promote controlled color emissions in MQW layers of an MQW region; forming the MQW region over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers where the alloyed percentage of Indium decreases with distance from the portions of the MQW layers that conform to the depressions; and forming a second active doped layer on the MQW region that is of opposite in charge to the first active doped layer.

A twelfth enumerated embodiment includes any of (or none of) the first through eleventh enumerated embodiments, further including: providing a transition region between each of the portions of the MQW layers conforming to the depressions and each of the other portions of the MQW layers and which transition region has a higher concentration of the alloyed percentage of Indium than the other portions of the MQW layers.

A thirteenth enumerated embodiment includes any of (or none of) the first through twelfth enumerated embodiments, further including: forming an electron blocking layer between the MQW region and the second active doped layer.

A thirteenth enumerated embodiment includes any of (or none of) the first through twelfth enumerated embodiments, further including: the depressions have an inner surface which is at angle with reference to the substrate between 0 and 90 degrees.

A fourteenth enumerated embodiment includes any of (or none of) the first through thirteenth enumerated embodiments, further including: the depressions have an inner surface which is at angle with reference to the substrate between 90 and 180 degrees.

A fifteenth enumerated embodiment includes any of (or none of) the first through fourteenth enumerated embodiments, further including: the depressions are spaced from each other at a distance between 150 nm and 10 μm.

A sixteenth enumerated embodiment includes any of (or none of) the first through fifteenth enumerated embodiments, further including: a depth difference between each of the depressions is a less than about 5 μm.

A seventeenth enumerated embodiment includes any of (or none of) the first through sixteenth enumerated embodiments, further including: the one or more shapes of the outer periphery of the depressions include one or more circles, triangles, squares, pentagons, or hexagons.

An eighteenth enumerated embodiment includes any of (or none of) the first through seventeenth enumerated embodiments, further including: the LED system is entirely formed in a common single material system.

A nineteenth enumerated embodiment includes any of (or none of) the first through eighteenth enumerated embodiments, further including: forming one or more driving circuitry elements which are coupled to the each of the one or more pixel elements.

A twentieth enumerated embodiment includes any of (or none of) the first through nineteenth enumerated embodiments, further including: a method for controlling one or more colored emissions, the method including: providing an LED system including a first active doped layer, an MQW region, and a second active dope layer; wherein the first active doped layer is selectively patterned along one surface opposite from the substrate with depressions in one or more shapes and with one or more spacing configurations to promote controlled color emissions in MQW layers of an MQW region; wherein the MQW region is formed over the one surface of the first active doped layer, wherein each of the MQW layers is alloyed with a percentage of Indium to promote the controlled color emissions, wherein portions of the MQW layers that conform to the depressions have a lower concentration of the alloyed percentage of Indium than other portions of the MQW layers where the alloyed percentage of Indium decreases with distance from the portions of the MQW layers that conform to the depressions; and wherein the second active doped layer is formed on the MQW region that is of opposite in charge to the first active doped layer; and varying an application of current over time to the LED system to alter the one or more color emissions.

A twenty-first enumerated embodiment includes any of (or none of) the first through twentieth enumerated embodiments, further including: the varying the application of current over time further includes: varying a duty-cycle and current level each wavelength of emission.

A twenty-second enumerated embodiment includes any of (or none of) the first through twenty-first enumerated embodiments, further including: the varying the application of current over time has a frequency is greater than 48 Hz.

A twenty-third enumerated embodiment includes any of (or none of) the first through twenty-second enumerated embodiments, further including: the varying the application of current over time further includes: mixing of two or more wavelengths each with a unique current level and duty-cycle in a single period.

A twenty-fourth enumerated embodiment includes any of (or none of) the first through twenty-third enumerated embodiments, further including: An LED system able to emit a variety of peak wavelengths of light in response to variations in driving current density, the system including: one or more pixel elements that each include one or more LEDs each including: a first active doped layer on a substrate and selectively patterned along one surface opposite from the substrate with depressions in one or more shapes and with one or more spacing configurations to promote controlled color emissions in MQW layers of an MQW region; the MQW region formed over the one surface of the first active doped layer, wherein each of the MQW layers is alloyed with an independent percentage of Indium to promote the controlled color emissions, wherein portions of the MQW layers that conform to the depressions have a lower concentration of the alloyed percentage of Indium than other portions of the MQW layers where the alloyed percentage of Indium decreases with distance from the portions of the MQW layers that conform to the depressions; and a second active doped layer formed on the MQW region that is of opposite in charge to the first active doped layer.

A twenty-fifth enumerated embodiment includes any of (or none of) the first through twenty-fourth enumerated embodiments, further including: an electron blocking layer between the MQW region and the second active doped layer.

A twenty-sixth enumerated embodiment includes any of (or none of) the first through twenty-fifth enumerated embodiments, further including: a method for controlling μ-LED displays, the μ-LED displays including a plurality of LED elements, each LED element including a plurality of MQW regions wherein each such MQW region is selectively doped to emit a desired color wavelength and such that each LED element emits a perceived single color wavelength that is a composite color of the desired color wavelengths of each MQW region, the method including: driving a first LED element in a first period of time to emit a first color in a first field; driving the first LED element in a second period of time to emit a second color in a second field to affect a Field Sequential Color which includes a perceived composite of the first and the second color.

A twenty-seventh enumerated embodiment includes any of (or none of) the first through twenty-sixth enumerated embodiments, further including: the first color of the first field and the second color of the second field form a first metamer for the perceived single color wavelength.

A twenty-eighth enumerated embodiment includes any of (or none of) the first through twenty-seventh enumerated embodiments, further including: a second LED element that is neighboring to the first LED element is driven in the first field to emit the second color and is driven in the second field emit the first color.

A twenty-nineth enumerated embodiment includes any of (or none of) the first through twenty-eighth enumerated embodiments, further including: the μ-LED display is affecting a spatial dither.

A thirtieth enumerated embodiment includes any of (or none of) the first through twenty-nineth enumerated embodiments, further including: the μ-LED display is affecting a Field Sequential Color sequence.

A thirty-first enumerated embodiment includes any of (or none of) the first through thirtieth enumerated embodiments, further including: the first LED element is driven in a third period of time to emit a third color in a third field and the first element is driven in a fourth period of time to emit a fourth color in a fourth field, such that the third color and fourth color are perceived as the same color as the first metamer.

A thirty-second enumerated embodiment includes any of (or none of) the first through thirty-first enumerated embodiments, further including: the desired perceived color may be rendered by a range of metamers selectable from a set of first colors and a set of second colors.

A thirty-third enumerated embodiment includes any of (or none of) the first through thirty-second enumerated embodiments, further including: the metamer selected to render the desired perceived color includes a metamer including the lowest difference in perceived brightness.

A thirty-fourth enumerated embodiment includes any of (or none of) the first through thirty-third enumerated embodiments, further including: the metamer selected to render the desired perceived color includes a metamer including the least power.

A thirty-fifth enumerated embodiment includes any of (or none of) the first through thirty-fourth enumerated embodiments, further including: a μ-LED display, the μ-LED displays including a plurality of LED elements, each LED element including a plurality of MQW regions wherein each such MQW region is selectively doped to emit a desired color wavelength and such that each LED element emits a perceived single-color wavelength that is a composite color of the desired color wavelengths of each MQW region, the μ-LED display further including: a metamer selection block, the metamer selection block receiving image input data, the image input data indicating a desired color and desired brightness to be rendered; the metamer selection block computing a metamer selection and brightness to be rendered by said LED element and at least one neighboring LED element such that the said LED element and the at least one neighboring LED element render the desired color and desired brightness in a spatio-temporal scheme.

A thirty-sixth enumerated embodiment includes any of (or none of) the first through thirty-fifth enumerated embodiments, further including: wherein the said LED element and at least one LED element render a first color and second color respectively, the first color and second color forming a metamer for the desired color to be rendered.

A thirty-seventh enumerated embodiment includes any of (or none of) the first through thirty-sixth enumerated embodiments, further including: the said LED element and at least one LED element are assigned a relative brightness value to render the desired brightness.

A thirty-seventh enumerated embodiment includes any of (or none of) the first through thirty-sixth enumerated embodiments, further including: the metamer selection block further includes a Look-Up Table of pre-calculated metamers.

A thirty-eighth enumerated embodiment includes any of (or none of) the first through thirty-seventh enumerated embodiments, further including: the metamer selection block further includes a Spatio-Temporal Pattern Generator block.

A thirty-nineth enumerated embodiment includes any of (or none of) the first through thirty-eighth enumerated embodiments, further including: the Spatio-Temporal Pattern Generator Block selects the color and brightness of each LED element according to the LED pattern that includes the μ-LED display.

A fortieth enumerated embodiment includes any of (or none of) the first through thirty-nineth enumerated embodiments, further including: the LED pattern includes one of a group, the group including: an array of LED elements, a checkboard of LED patterns.

A forty-first enumerated embodiment includes any of (or none of) the first through fortieth-enumerated embodiments, further including: the μ-LED display further includes a SubPixel Rendering (SPR) block.

A forty-second enumerated embodiment includes any of (or none of) the first through forty-first enumerated embodiments, further including: the SPR block includes a plurality of SPR filters, the SPR filters including kernals that affect a subpixel rendering to neighboring LED elements.

Having thus described the basic concept of the technology, it will be rather apparent to those skilled in the art that the foregoing detailed disclosure is intended to be presented by way of example only and is not limiting. Various alterations, improvements, and modifications will occur and are intended to those skilled in the art, though not expressly stated herein. These alterations, improvements, and modifications are intended to be suggested hereby, and are within the spirit and scope of the technology. Additionally, the recited order of processing elements or sequences, or the use of numbers, letters, or other designations therefore, is not intended to limit the scope of the present application.

What is claimed is:

1. A method for controlling μ-LED displays, the μ-LED displays comprising a plurality of LED elements, each LED element comprising a plurality of MQW regions wherein each such MQW region is selectively able to emit one or more desired color wavelengths and such that each LED element emits a perceived single color wavelength that is a composite color of the desired color wavelengths of each MQW region, the method comprising:
driving a first LED element in a first period of time to emit a first color in a first field;
driving the first LED element in a second period of time to emit a second color in a second field to affect a Field Sequential Color which comprises a perceived composite of the first and the second color.

2. The method of claim 1 wherein the first color of the first field and the second color of the second field form a first metamer for the perceived single color wavelength.

3. The method of claim 2 wherein a second LED element that is neighboring to the first LED element is driven in the first field to emit the second color and is driven in the second field emit the first color.

4. The method of claim 3 wherein the μ-LED display is affecting a spatial dither.

5. The method of claim 4 wherein the μ-LED display is affecting a Field Sequential Color sequence.

6. The method of claim 2 wherein the first LED element is driven in a third period of time to emit a third color in a third field and the first element is driven in a fourth period of time to emit a fourth color in a fourth field, such that the third color and fourth color are perceived as the same color as the first metamer.

7. The method of claim 2 wherein the desired perceived color may be rendered by a range of metamers selectable from a set of first colors and a set of second colors.

8. The method of claim 7 wherein the metamer selected to render the desired perceived color comprises a metamer comprising the lowest difference in perceived brightness.

9. The method of claim 7 wherein the metamer selected to render the desired perceived color comprises a metamer comprising the least power.

10. A μ-LED display, the μ-LED displays comprising a plurality of LED elements, each LED element comprising a plurality of MQW regions wherein each such MQW region is selectively doped to emit a desired color wavelength and such that each LED element emits a perceived single-color wavelength that is a composite color of the desired color wavelengths of each MQW region, the μ-LED display further comprising:
a metamer selection block, the metamer selection block receiving image input data, the image input data indicating a desired color and desired brightness to be rendered;
the metamer selection block computing a metamer selection and brightness to be rendered by said LED element and at least one neighboring LED element such that the said LED element and the at least one neighboring LED element render the desired color and desired brightness in a spatio-temporal scheme.

11. The μ-LED display of claim 10 wherein the said LED element and at least one LED element render a first color and second color respectively, the first color and second color forming a metamer for the desired color to be rendered.

12. The μ-LED display of claim 11 wherein the said LED element and at least one LED element are assigned a relative brightness value to render the desired brightness.

13. The μ-LED display of claim 12 wherein the metamer selection block further comprises a Look-Up Table of pre-calculated metamers.

14. The μ-LED display of claim 13 wherein the metamer selection block further comprises a Spatio-Temporal Pattern Generator block.

15. The μ-LED display of claim 14 wherein the Spatio-Temporal Pattern Generator Block selects the color and brightness of each LED element according to the LED pattern that comprises the μ-LED display.

16. The μ-LED display of claim 14 wherein the LED pattern comprises one of a group, the group comprising: an array of LED elements, a checkboard of LED patterns.

17. The μ-LED display of claim 16 wherein the μ-LED display further comprises a SubPixel Rendering (SPR) block.

18. The μ-LED display of claim 17 wherein the SPR block comprises a plurality of SPR filters, the SPR filters comprising kernals that affect a subpixel rendering to neighboring LED elements.
